(19) United States
(12) Patent Application Publication
(10) Pub. No.: US 2016/0312116 A1
(43) Pub. Date: Oct. 27, 2016

(54) FLUORESCENT MATERIAL FOR WHITE LIGHT EMITTING DIODE AND PREPARATION METHOD THEREOF

(71) Applicant: Daejoo Electronic Materials Co., Ltd, Gyeonggi-do (KR)

(72) Inventors: Sanghyuk Han, Incheon (KR); Kyoung Hoon Kim, Incheon (KR); Il Ji Lim, Seoul (KR)

(21) Appl. No.: 14/783,646

(22) PCT Filed: Nov. 13, 2013
(86) PCT No.: PCT/KR2013/010294

§ 371 Date: Oct. 9, 2015

(30) Foreign Application Priority Data
Apr. 9, 2013 (KR) 10-2013-0038561

(51) Int. Cl. C09K 11/77; H01L 33/50

(52) U.S. Cl. CPC C09K 11/7774; H01L 33/502

(57) ABSTRACT

A fluorescent material of a garnet structure having an aluminate-based fluorescent material, cerium as an activator and thulium as a coactivator can emit green light with high luminance under an excitation condition by a blue light source, and therefore, it is useful as a fluorescent material for a white light emitting diode.

### FIELD OF THE INVENTION

The present invention relates to a fluorescent material for a white light emitting diode, a preparation method thereof, and a white light emitting diode using same.

### BACKGROUND OF THE INVENTION

A white light emitting diode (LED) is one of next generation LEDs replaceable with a common lighting. As a red LED, a green LED and a blue LED having high luminance are commercialized, a white LED obtainable by combination of the above-mentioned three color LEDs has been developed.

After that, due to rapid technical progress, an LED which can exhibit white light by combination of blue and yellow lights has been reported. In other words, the white LED has the structure that a 460 nm-wavelength blue light source of a blue LED having sufficient excitation energy illuminates a yellow fluorescent material, emitting yellow light, which can exhibit desired white light (Korean Laid-Open Patent Publication No. 2002-72964).

However, in order to manufacture a white LED having high color rendering properties and color gamut, there has been a need to develop a green fluorescent material which is excited by blue light generated from a blue LED and can emit green light with high luminance.

### SUMMARY OF THE INVENTION

Therefore, it is an object of the present invention to provide a high luminance fluorescent material for a white light emitting diode (LED), a preparation method thereof, and a white LED comprising same.

In accordance with one aspect of the present invention, there is provided a fluorescent material for a white LED comprising a garnet structure of Chemical Formula (I):

(LuₓTm_{y}Ce_{z})₃Al₅O₁₂ (I)

wherein, 0.5≦x≦0.99, y>0, z>0 and x+y+z=1.

In accordance with another aspect of the present invention, there is provided a preparation method of a fluorescent material comprising the steps of: (a) mixing lutetium oxide, thulium oxide, cerium oxide and aluminum oxide to prepare a mixture of raw materials; (b) drying the resulting raw material mixture and calcining it at a temperature ranging from 1,200° C. to 1,700° C.; and (c) pulverizing the calcined material thus obtained.

In accordance with still another aspect of the present invention, there is provided a white LED comprising the fluorescent material.

The fluorescent material of the present invention which comprises an aluminate-based fluorescent material, cerium as an activator and thulium as a coactivator can emit green light with high luminance under an excitation condition by a blue light source, and therefore, it is useful as a fluorescent material for a white LED.

### BRIEF DESCRIPTION OF THE DRAWINGS

The above and other objects and features of the present invention will become apparent from the following description of the invention, when taken in conjunction with the accompanying drawings, which respectively show:

FIG. 1: a scanning electron microscope image of the fluorescent material prepared in Example 1;

FIG. 2: a light emitting spectrum of each of fluorescent materials with and without thulium; and

FIG. 3: a light emitting spectrum of the white LED prepared in Example 4.

### DETAILED DESCRIPTION OF THE INVENTION

### Fluorescent Material for White LED

The fluorescent material for a white LED of the present invention is represented by Chemical Formula (I):

(LuₓTm_{y}Ce_{z})₃Al₅O₁₂ (I)

wherein, 0.5≦x≦0.99, y>0, z>0 and x+y+z=1.

In one embodiment of x, x may be in a range of 0.6≦x≦0.99, in a range of 0.7≦x≦0.99, in a range of 0.8≦x≦0.99, or in a range of 0.9≦x≦0.99. In another embodiment, x may be in a range of 0.9≦x≦0.95, in a range of 0.9≦x≦0.96, in a range of 0.9≦x≦0.97, or in a range of 0.9≦x≦0.98. In still another embodiment, x may be in a range of 0.95≦x≦0.96, in a range of 0.95≦x≦0.97, in a range of 0.95≦x≦0.98, or in a range of 0.95≦x≦0.99.

In one embodiment of y, y may be in a range of 0<y<0.5, in a range of 0<y≦0.4, in a range of 0<y≦0.3, in a range of 0<y≦0.2, or in a range of 0<y≦0.1. In another embodiment, y may be in a range of 0<y≦0.05, in a range of 0<y≦0.04, in a range of 0<y≦0.03, in a range of 0<y≦0.02, in a range of 0<y≦0.01, or in a range of 0<y≦0.005. In still another embodiment, y may be in a range of 0.001<y≦0.05, in a range of 0.001≦y≦0.04, in a range of 0.001≦y≦0.03, in a range of 0.001≦y≦0.02, in a range of 0.001≦y≦0.01, or in a range of 0.001≦y≦0.005.

In one embodiment of z, z may be in a range of 0<z<0.5, in a range of 0<z≦0.4, in a range of 0<z≦0.3, in a range of 0<z≦0.2, or in a range of 0<z≦0.1. In another embodiment, z may be in a range of 0<z≦0.09, in a range of 0<z≦0.08, in a range of 0<z≦0.07, in a range of 0<z≦0.06, or in a range of 0<z≦0.05. In still another embodiment, z may be in a range of 0.005<z≦0.09, in a range of 0.005≦z≦0.08, in a range of 0.005≦z≦0.07, in a range of 0.005≦z≦0.06, or in a range of 0.005≦z≦0.05. In a further another embodiment, z may be in a range of 0.03≦z≦0.08, in a range of 0.04≦z≦0.08, in a range of 0.05≦z≦0.08, or in a range of 0.05≦z≦0.07.

In one embodiment of y and z, the ratio of y:z may be in a range of 20:1 to 1:20, in a range of 15:1 to 1:15, in a range of 10:1 to 1:10, in a range of 5:1 to 1:5, in a range of 3:1 to 1:3, in a range of 2:1 to 1:2, or in a range of 1.5:1 to 1:1.5. In another embodiment, the ratio of y:z may be in a range of 1:1 to 1:20, in a range of 1:1 to 1:15, in a range of 1:1 to 1:10, in a range of 1:1 to 1:5, in a range of 1:1 to 1:3, in a range of 1:1 to 1:2, or in a range of 1:1 to 1:1.5.

In addition, the garnet structure of Chemical Formula (I) may further comprise at least one of A and B. That is, the fluorescent material for a white LED of the present invention may be represented by Chemical Formula (II):

(LuₓTm_{y}Ce_{z}AₐB_{b})₃Al₅O₁₂ (II)

wherein, 0.5≦x≦0.99, y>0, z>0 and x+y+z=1;

A is an alkali metal, and B is a rare earth metal; and

0≦a≦0.05, 0≦b≦0.05, and 0<a+b<0.1.

The alkali metal may include Li, K, or a combination thereof. The rare earth metal may include La, Nd, Pm, Eu, Gd, Tb, Dy, Ho, Er, Yb, or a combination thereof.

Various ranges may be applicable for x, y and z, and particular examples are the same as those illustrated regarding Chemical Formula (I).

In one embodiment of a, a may be in a range of 0≦a≦0.05, in a range of 0≦a≦0.04, in a range of 0≦a≦0.03, in a range of 0≦a≦0.02, or in a range of 0≦a≦0.01. In another embodiment, a may be in a range of 0.001≦a≦0.05, in a range of 0.001≦a≦0.04, in a range of 0.001≦a≦0.03, in a range of 0.001≦a≦0.02, or in a range of 0.001≦a≦0.01.

In one embodiment of b, b may be in a range of 0≦b≦0.05, in a range of 0≦b≦0.04, in a range of 0≦b≦0.03, in a range of 0≦b≦0.02, or in a range of 0≦b≦0.01. In another embodiment, b may be in a range of 0.001≦b≦0.05, in a range of 0.001≦b≦0.04, in a range of 0.001≦b≦0.03, in a range of 0.001≦b≦0.02, or in a range of 0.001≦b≦0.01.

The fluorescent material of the present invention may be in a powder state. In this case, the particle diameter of the powder may be in a range of 5 μm to 50 μm. For example, the particle diameter of the powder may be in a range of 10 μm to 50 μm, in a range of 10 μm to 40 μm, in a range of 10 μm to 30 μm, or in a range of 15 μm to 25 μm, and the values are particle diameters when considering an average diameter D₅₀.

The fluorescent material of the present invention may be sufficiently excited by near-ultraviolet light or blue light, and then emit light. Particularly, the fluorescent material for the white LED of the present invention may emit green light or yellowish green light. According to an example embodiment, the fluorescent material for the white LED of the present invention may emit light having a wavelength ranging from 470 nm to 600 nm, from 490 nm to 575 nm, or from 520 nm to 550 nm. In addition, a light emission peak of the fluorescent material may be in a range of from about 530 nm to 540 nm.

The fluorescent material of the present invention may be excited by near-ultraviolet light or a light source generated from a blue LED, and it may exhibit excellent light emitting efficiency and high luminance. Therefore, the inventive fluorescent material can be used in the manufacture of a white LED. Particularly, cerium ions function as an activator to emit green light, and thulium ions added together with the cerium ions function as a coactivator to transfer energy to the cerium ions, greatly contributing to the green light emission. Trivalent thulium ions (Tm³⁺) are stable at room temperature and in the atmosphere. Thus, the lifetime of the fluorescent material may be prolonged, and the stability of reduced cerium ions may be increased. In addition, since the thulium ions control the replacement of cerium and surface defects to assist crystal growth, consequently, an increase in the intensity of light emission may be expected.

### Preparation Method of Fluorescent Material for White LED

The fluorescent material of the present invention is prepared by a method comprising the steps of: (a) mixing lutetium oxide, thulium oxide, cerium oxide and aluminum oxide to prepare a mixture of raw materials; (b) drying the resulting raw material mixture and calcining at a temperature of 1,200° C. to 1,700° C.; and (c) pulverizing the calcined material thus obtained.

In step (a), raw materials comprising lutetium oxide, thulium oxide, cerium oxide and aluminum oxide are mixed.

The used amount of each of lutetium oxide, thulium oxide, cerium oxide and aluminum oxide may be controlled diversely. Particularly, the used amount may be appropriately controlled so that the final fluorescent material has x, y and z values defined in Chemical Formula (I).

In step (a), an oxide of an alkali metal, an oxide of a rare earth metal, or a mixture thereof may be additionally subjected to mixing. In this case, the used amount of each of the alkali metal and the oxide of the rare earth metal may be controlled diversely. Particularly, the used amount may be appropriately controlled so that the final fluorescent material has a and b values defined in Chemical Formula (II).

The mixing of the raw materials may be sufficiently conducted in an alcohol solvent such as ethanol, by means of ball milling or using a mixer such as an agate mortar to form a homogeneous composition.

In step (b), the raw material mixture thus obtained are dried and calcined at a temperature ranging from 1,200° C. to 1,700° C.

The drying may be conducted, for example, in an oven at a temperature ranging from 100° C. to 150° C. for 12 to 36 hours.

Then, the dried mixture may be put into a high purity alumina crucible, etc. and may be calcined using an electrical furnace, etc. In this case, when the calcining temperature is less than 1,200° C., a phase formation may be bad, and when the calcining temperature is 1,700° C. or above, non-uniform particle growth may be induced due to over-calcining, resulting in lowering of luminance. The calcining time may be 1 to 10 hours.

In step (c), the calcined material thus obtained is subject to pulverization to form a powder. The pulverization may be conducted by ball milling, etc.

### Application of Fluorescent Material for White LED

The fluorescent material of the present invention may be used as a color changing fluorescent material of near ultraviolet light or a blue LED. The inventive fluorescent material is coated on the near-ultraviolet light or blue LED and excited thereby, emitting green light. Accordingly, the inventive fluorescent material may be used in the manufacture of a white LED in combination with a red-emitting fluorescent material.

According to the present invention, a white LED comprising the fluorescent material of the present invention is provided. More particularly, the present invention provides a white LED comprising a blue LED, and the fluorescent material of the present invention and a red fluorescent material which are coated thereon.

In addition, the present invention provides a light emitting apparatus, a lighting apparatus and a backlight unit (BLU) comprising the white LED.

Hereinafter, the present invention is described in detail referring to preferred embodiments. However, the present invention is not limited to the following embodiments.

### Example 1: Preparation of (Lu_{0.985}Tm_{0.005}Ce_{0.01})₃Al₅O₁₂ Fluorescent Material

1.4775 mol of lutetium oxide (Lu₂O₃), 0.0075 mol of thulium oxide (Tm₂O₃), 0.03 mol of cerium oxide (CeO₂), and 2.5 mol of aluminum oxide (Al₂O₃) were homogeneously mixed by using an agate mortar.

The resulting raw material mixture was dried in an oven at 130° C. for 24 hours. Then, the mixture was put into a high purity alumina boat and calcined in a reduction atmosphere at 1,450° C. for 4 hours by using an electrical furnace.

The calcined material thus obtained was added into distilled water, crushed using a stirrer, and treated with ball mills to obtain a green fluorescent material represented by (Lu_{0.985}Tm_{0.005}Ce_{0.01})₃Al₅O₁₂.

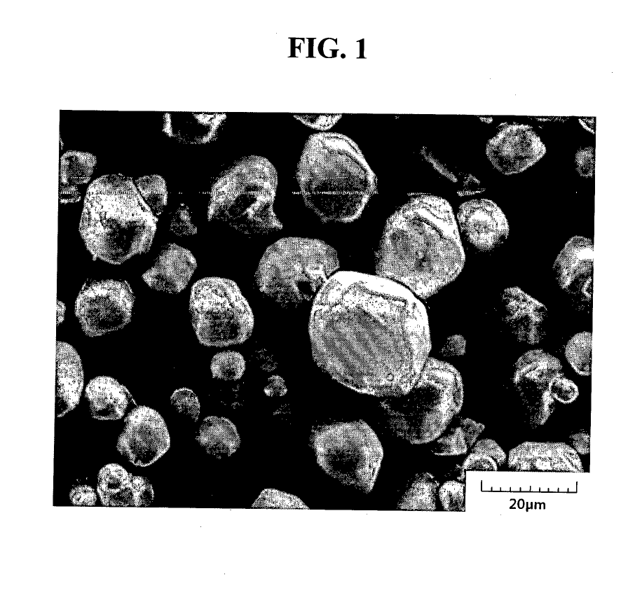

The surface structure of the fluorescent material thus prepared was observed by a scanning electron microscope and illustrated in FIG. 1. As illustrated in FIG. 1, an aluminate-based green fluorescent material of the present invention is in a powder state having a particle diameter of about 5 μm to 50 μm.

### Example 2: Measurement of Change in Light Emission Intensity of Fluorescent Material Depending on Amount of Cerium

The same procedure as explained in Example 1 was repeated except that the used amounts of the lutetium oxide and the cerium oxide were changed to prepare green fluorescent materials in a powder state represented by (Lu_{0.995-z}Tm_{0.005}Ce_{z})₃Al₅O₁₂ (z=0.03, 0.04, 0.05, 0.06, 0.07 or 0.08). The light emission intensity, the color coordinate and the particle diameter of the fluorescent materials were measured and illustrated in following Table 1.

TABLE 1

| Composition | Light emission | | | Particle diameter (μm) | | | |
|---|---|---|---|---|---|---|---|
| z | Intensity | CIE x | CIE y | D₁₀ | D₅₀ | D₉₀ | Dₘₐₓ |
| 0.03 | 96.8 | 0.334 | 0.574 | 9.51 | 17.86 | 27.08 | 52.02 |
| 0.04 | 102.8 | 0.343 | 0.573 | 13.14 | 18.71 | 26.95 | 51.99 |
| 0.05 | 104.8 | 0.364 | 0.565 | 12.64 | 17.71 | 25.35 | 51.86 |
| 0.06 | 104.9 | 0.373 | 0.561 | 13.13 | 18.13 | 25.81 | 51.90 |
| 0.07 | 104.0 | 0.382 | 0.557 | 13.76 | 18.75 | 26.40 | 51.87 |
| 0.08 | 104.1 | 0.393 | 0.551 | 14.08 | 19.15 | 26.91 | 51.89 |

As shown in Table 1, the fluorescent material obtained in the Examples exhibited good light emission intensity. Particularly, the light emission intensity was the highest when the amount of cerium, z, was in the range of 0.05 to 0.07. In addition, change in the color of the emitted light was observed as the amount of cerium (z) increased. That is, x value increased and y value decreased in a CIE color coordinate, which meant that the light emission wavelength of the fluorescent material became longer. Such change of the wavelength can lead to enhancement of color rendering index (CRI) and color gamut. Not much change was observed with the particle diameter of the fluorescent material according to the added amount of cerium.

### Example 3: Comparison of Light Emission Spectrum of Fluorescent Material Depending on the Presence of Thulium

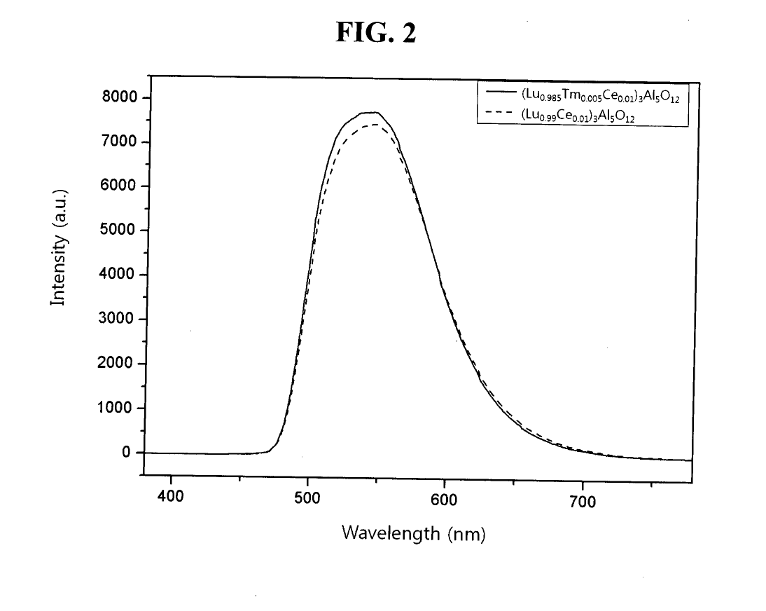

A (Lu_{0.99}Ce_{0.01})₃Al₅O₁₂ fluorescent material was prepared as a Comparative Example, and a light emission spectrum thereof along with that of the (Lu_{0.985}Tm_{0.005}Ce_{0.01})₃Al₅O₁₂ fluorescent material prepared in Example 1 was measured. The results are shown in FIG. 2.

As shown in FIG. 2, the green fluorescent material of the present invention including cerium and thulium in amounts of 0.01 mol and 0.005 mol, respectively, exhibited green light emission having a maximum peak wavelength of 530 nm. When compared with the light emission spectrum of the (Lu_{0.99}Ce_{0.01})₃Al₅O₁₂ fluorescent material, the green fluorescent material of the present invention was confirmed to have even higher light emitting luminance.

### Example 4: Manufacture of White LED using Green Fluorescent Material

On a blue LED, the (Lu_{0.985}Tm_{0.005}Ce_{0.01})₃Al₅O₁₂ fluorescent material prepared in Example 1 and a red fluorescent material (BR-102C, Mitsubishi Chemical Co.) were coated to manufacture a white LED.

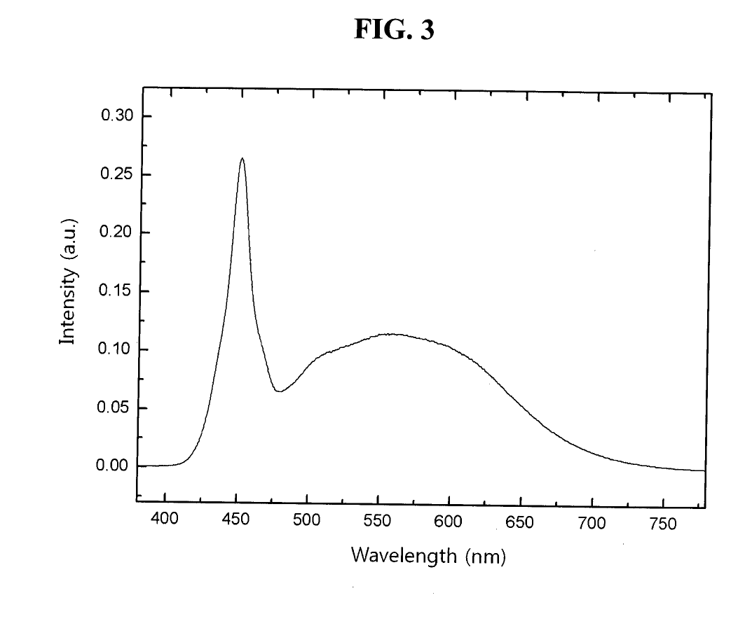

A light emission spectrum of the fluorescent material of Example 1 by an excitation light of the blue LED is illustrated in FIG. 3. As illustrated in FIG. 3, the fluorescent material of Example 1 exhibited a good green light emission under blue excitation light of 455 nm, and the green light was mixed with red light from the red fluorescent material to exhibit a light emission peak over about 500 nm to 650 nm.

As a result, it is confirmed that the blue excitation light, the red light and the green light were mixed, exhibiting desired white light.

While the invention has been described with respect to the above specific embodiments, it should be recognized that various modifications and changes may be made to the invention by those skilled in the art which also fall within the scope of the invention as defined by the appended claims.

1. A fluorescent material for a white light emitting diode, comprising a garnet structure of Chemical Formula (I):
(LuₓTm_{y}Ce_{z})3Al₅O₁₂ (I)
wherein 0.5≦x≦0.99, y>0, z>0, and x+y+z=1.

2. The fluorescent material of claim 1, wherein y is in a range of 0.001≦y≦0.01.

3. The fluorescent material of claim 1, wherein z is in a range of 0.005≦z≦0.09.

4. The fluorescent material of claim 1, wherein z is in a range of 0.05≦z≦0.07.

5. The fluorescent material of claim 1, wherein the garnet structure of Chemical Formula (I) further comprises at least one of A and B, and is represented by Chemical Formula (II):
(LuₓTm_{y}Ce_{z}AₐB_{b})₃Al₅O12 (II)
wherein,
0.5≦x≦0.99, y>0, z>0 and x+y+z=1;
A is an alkali metal, and B is a rare earth metal; and
0≦a≦0.05, 0≦b≦0.05, and 0<a+b<0.1.

6. The fluorescent material of claim 5, wherein the alkali metal is selected from the group consisting of Li, K and a combination thereof.

7. The fluorescent material of claim 5, wherein the rare earth metal is selected from the group consisting of La, Nd, Pm, Eu, Gd, Tb, Dy, Ho, Er, Yb and a combination thereof.

8. The fluorescent material of claim 1, wherein the fluorescent material is in a powder state and has a particle diameter of 5 μm to 50 μm.

9. The fluorescent material of claim 1, wherein the fluorescent material emits light having a wavelength ranging from 470 nm to 600 nm.

10. A method for preparing the fluorescent material of claim 1, which comprises the steps of:
(a) mixing lutetium oxide, thulium oxide, cerium oxide and aluminum oxide to prepare a mixture of raw materials;
(b) drying the resulting raw material mixture and calcining it at a temperature ranging from 1,200° C. to 1,700° C.; and
(c) pulverizing the calcined materials thus obtained.

11. The method of claim 10, wherein in step (a), an oxide of an alkali metal, an oxide of a rare earth metal, or a mixture thereof is further subjected to mixing.

12. A white light emitting diode comprising the fluorescent material according to claim 1.

13. A light emitting apparatus comprising the white light emitting diode of claim 12.

14. A lighting apparatus comprising the white light emitting diode of claim 12.

15. A backlight unit comprising the white light emitting diode of claim 12.
